(19) United States
(12) Patent Application Publication
(10) Pub. No.: US 2026/0360424 A1
(43) Pub. Date: Nov. 12, 2026

(54) STORAGE ARRAY AND OPERATION METHOD THEREFOR

(71) Applicant: PEKING UNIVERSITY, Beijing (CN)

(72) Inventors: Zongwei WANG, Beijing (CN); Yimao CAI, Beijing (CN); Yuhang YANG, Beijing (CN); Jingwei SUN, Beijing (CN)

(73) Assignee: PEKING UNIVERSITY, Beijing (CN)

(21) Appl. No.: 19/202,813

(22) Filed: May 8, 2025

(30) Foreign Application Priority Data
Mar. 8, 2024 (CN) 202410265948.3

(51) Int. Cl. G11C 13/00

(52) U.S. Cl. CPC G11C 13/0069; G11C 13/0026; G11C 13/0028; G11C 13/004

(57) ABSTRACT

A storage array is provided in the present disclosure, which includes K storage cells arranged in parallel. Each of the storage cells includes N gating transistors, N×M two-end storage devices, a source line, a word line, and N×M bit lines. A drain-source series structure is formed by connecting a drain of a previous gating transistor to a source of a subsequent gating transistor among the N transistors. Gates of the drain-source series structure are all connected to the word line. A source of the first gating transistor in the drain-source series structure is connected to the source line. Every M two-end storage devices are grouped, with a total of N groups corresponding to the N gating transistors. In each of the groups, one end of each of the storage devices is interconnected and connected to the drain of a corresponding gating transistor. The other ends are connected to M bit lines, respectively. The storage cells of the storage array share N×M common bit lines.

### RELATED APPLICATION

The present disclosure claims priority to Chinese patent No. 202410265948.3, filed on Mar. 8, 2024, and entitled “HIGH-DENSITY STORAGE ARRAY”, the content of which is hereby incorporated by reference in its entirety.

### TECHNICAL FIELD

The present disclosure relates to the technical field of memory and CMOS hybrid integrated circuit, in particular to a storage array.

### BACKGROUND

The rapid increase in information data volume in modern society has imposed relatively high requirements on existing memories. Currently, mainstream non-volatile memories are NAND-structure-based FLASH. However, FLASH memories have issues such as high operating voltage and difficulty in scaling down. In order to address anticipated technical problems for storage, various non-volatile memories have been provided, such as Resistive Random Access Memory (RRAM), Phase-change Random Access Memory (PRAM), Magnetoresistive Random Access Memory (MRAM), and Ferroelectric Random Access Memory (FeRAM).

Among various new types of non-volatile memories, two-end non-volatile memories have received extensive attention and research due to their relatively high theoretical density and relatively low process costs brought by simple structures. In practical applications, two-end memories need to form a storage array to achieve a high-density structure and high-speed reading and writing.

### SUMMARY

In view of the above technical problems in the related art, a storage array and an operation method therefor are provided in the present disclosure.

A storage array is provided in the present disclosure, wherein each of the storage cells includes N gating transistors, N×M two-end storage devices, a source line, a word line, and N×M bit lines. A drain-source series structure is formed by connecting a drain of a previous gating transistor to a source of a subsequent gating transistor among the N transistors. Gates of the drain-source series structure are all connected to the word line. A source of the first gating transistor in the drain-source series structure is connected to the source line. Every M two-end storage devices are grouped, with a total of N groups corresponding to the N gating transistors. In each of the groups, ends of the storage devices are interconnected and connected to the drain of the corresponding gating transistor, and the other ends are connected to M bit lines, respectively. The K storage cells of the storage array share N×M common bit lines, and N×M bit lines of each of the storage cells are connected to the N×M common bit lines, respectively.

In some embodiments, the two-end storage device has at least two variable states for storing data, and the two-end storage device includes a resistive random access memory, a spin transfer torque magnetoresistive random access memory, or a phase-change random storage.

In some embodiments, the gating transistor includes a MOSFET.

In some embodiments, K is not smaller than two.

In another aspect, an operation method for a storage array of any of the above embodiments is provided in the present disclosure, which includes controlling a voltage of a word line to turn on N gating transistors of a storage cell to be read when performing a read operation on the storage array, and then applying a read signal to a corresponding bit line and reading a current of a corresponding source line to read a resistance state of a storage device; or
controlling the voltage of the word line to turn on N gating transistors of a storage cell to be written when performing a write operation on the storage array, and then applying a write signal to a bit line or a source line to change a resistance state of a storage device.

Details in one or more embodiments of the present disclosure are provided in the accompanying drawings and description below. Other features, objectives, and advantages of the present disclosure may be more clear based on the specification, the drawings, and the claims.

### BRIEF DESCRIPTION OF THE DRAWINGS

FIG. 1 is a schematic structural view of a 1T1R array.

FIG. 2 is a schematic structural view of a storage array provided in the present disclosure.

FIG. 3 is a schematic structural view of an array of Embodiment 1 in the present disclosure.

FIG. 4 is a schematic view of an operation method corresponding to FIG. 3.

FIG. 5 is a schematic structural view of an array of Embodiment 2 in the present disclosure.

FIG. 6 is a schematic view of an operation method corresponding to FIG. 5.

### DETAILED DESCRIPTION

The present disclosure is elaborated more clearly and completely below with reference to the accompanying drawings and specific embodiments.

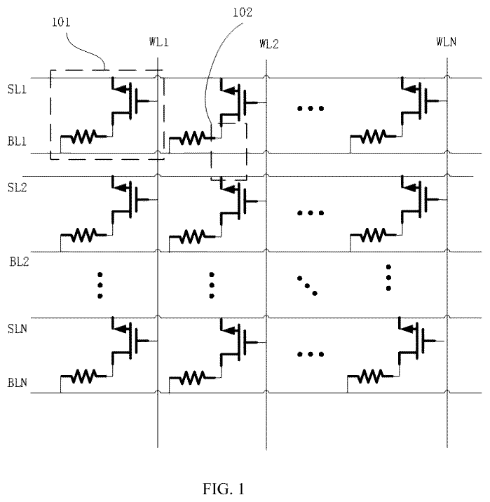

FIG. 1 illustrates an array includes 1T1R (one transistor one resistor) storage cells. The array can be regarded as being formed by arranging the 1T1R storage cells 101 in the horizontal and vertical directions. Each of the storage cells includes a gating transistor N and a storage device R. When reading data, transistors of storage devices of a corresponding column are turned on through a signal of a word line WL. At this point, states corresponding to the storage devices can be read by applying a read voltage through a signal of a bit line BL and by detecting a read current corresponding to a source line SL. When writing data, the transistors of a corresponding column are turned on by applying a signal to the word line WL, and then a write voltage is applied to the bit line BL or the source line SL to write a desired resistance value into the storage device R.

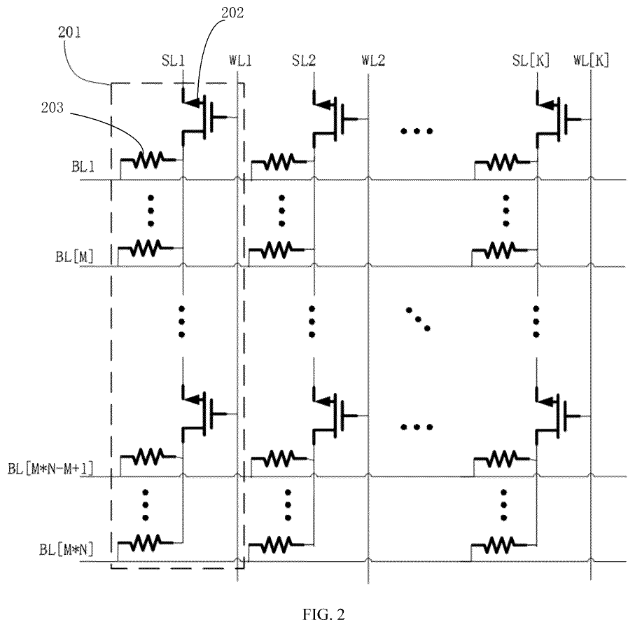

However, the density of the 1T1R array shown in FIG. 1 is limited by the area occupied by the transistors, which is mainly restricted by the parts 102. Firstly, each of the transistors is only connected to one storage device. Secondly, the source of a lower transistor needs to be connected to a source line SL, and thus the source of the lower transistor and the drain of an upper transistor need to be isolated, which brings additional area overhead. These two factors jointly limit the further improvement of the density of the storage array. Therefore, developing a storage array is of great significance. The present disclosure provides a storage array, for example, a high-density storage array. As shown in FIG. 2, a circuit of the storage array includes K storage cells 201 arranged in parallel. K source lines SL and K word lines WL corresponding to the K storage cells are labeled in FIG. 2. All storage cells share M×N bit lines BL, that is, the M×N bit lines of each storage cell are respectively connected to M×N common bit lines. The corresponding M×N bit lines BL, i.e., BL₁, . . . , BL[M], . . . , BL[M×N−M+1], . . . , BL[M×N], are shown in FIG. 2.

In FIG. 2, a storage cell 201 includes N gating transistors 202, M×N two-end storage devices 203, a source line SL, a word line WL, and M×N bit lines BL. A drain-source series structure is formed by connecting the drain of each previous gating transistor to the source of the subsequent gating transistor among the N transistors. The gates of the drain-source series structure are all connected to the word line WL. The source of the first gating transistor in the drain-source series structure is connected to the source line SL. Every M storage devices are grouped such that ends of the storage devices are interconnected and connected to the drain of a gating transistor, while the other ends of the storage devices are connected to the corresponding bit lines BL, respectively. As such, M×N storage devices and N gating transistors form a storage cell.

When performing a read operation on the storage array provided in the present disclosure, the N gating transistor of a storage cell to be read can be turned on by controlling the voltage of the corresponding word line WL, and then the resistance state of a storage device can be read by applying a read signal to the corresponding bit line BL and reading the current of the corresponding source line. When writing, the N gating transistors of the storage cell to be written can be turned on by controlling the voltage of the word line WL, and then the resistance state of the storage device can be changed by applying a write signal to the corresponding bit line or source line to write a desired state into the storage device.

### Embodiment 1

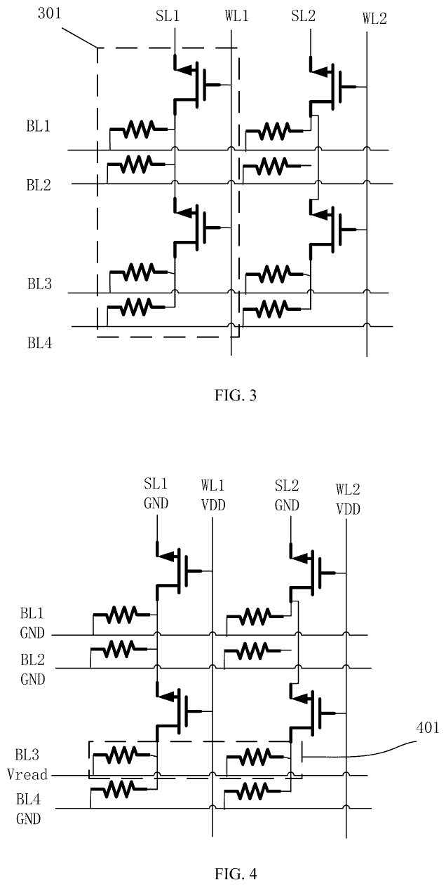

The storage array in FIG. 3 can be regarded as including two storage cells 301, i.e., K=2. For each of the storage cells, M=2 and N=2, that is, each of the storage cells includes two gating transistors, four storage devices, one source line SL, one word line WL, and four bit lines BL. The source of the lower gating transistor is connected to the drain of the upper gating transistor. The two gating transistors form a drain-source series structure in which all the gates are connected to the word line WL and the source of the upper gating transistor is connected to the source line SL. Ends of every two storage devices are interconnected and connected to the drain of one of the gating transistors. As such, the four storage devices are connected to the drains of the two transistors, and the other ends of the four storage devices are connected to the corresponding bit lines BL, respectively. Resistive Random Access Memories (RRAMs) are used as the storage devices in this embodiment.

Assuming that it is required to read the resistance states of the two storage devices corresponding to the bit line BL3, that is, the resistance states of the two storage devices 401 in FIG. 4, the corresponding operation method is shown in FIG. 4. In this case, both word lines WL1 and WL2 are connected to VDD, and all transistors are turned on. The bit line BL3 is connected to a voltage Vread, and the remaining bit lines BL are connected to GND. All source lines SL are connected to GND. The resistance states of the two storage devices corresponding to the bit line BL3 can be obtained by reading the currents on the source lines SL1 and SL2, so as to read the stored information.

### Embodiment 2

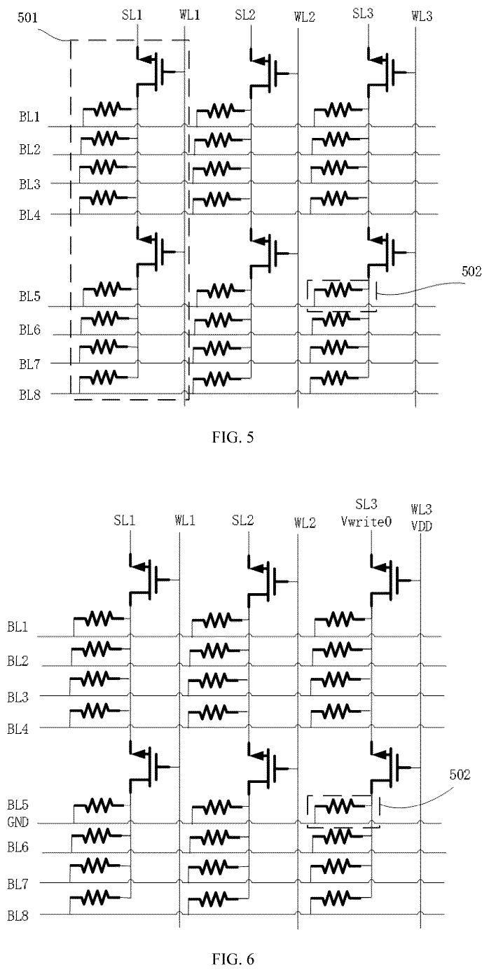

FIG. 5 shows a structure of a storage array of another specific embodiment in the present disclosure. The array in FIG. 5 can be regarded as including three storage cells 501, i.e., K=3. For each of the storage cells, M=4 and N=2, that is, each of the storage cell includes two gating transistors, eight storage devices, one source line SL, one word line WL, and eight bit lines BL. The source of the lower gating transistor is connected to the drain of the upper gating transistor. The two gating transistors form a drain-source series structure in which all the gates thereof are connected to the word line WL. The source of the upper gating transistor is connected to the source line SL. Ends of every four storage devices are interconnected and connected to the drain of one of the gating transistors. As such, the eight storage devices are connected to the drains of the two transistors, and the other ends of the eight storage devices are connected to the corresponding bit lines BL, respectively. Phase-change Random Access Memories (PRAMs) are used as the storage devices of this embodiment.

Assuming that it is required to write the storage device 502 corresponding to the bit line BL5 and source line SL3 from a low resistance state to a high resistance state without affecting the states of other devices, the method for applying operating voltage is shown in FIG. 6. In this case, word line WL3 is connected to VDD and the corresponding transistor is in an on-state. The source line SL3 is connected to a write voltage Vwrite0 required for writing 0 into the storage device. The bit line BL5 and all remaining unlabeled word lines WL, bit lines BL, and source lines SL are connected to GND. At this point, current flows through the storage device 502, and the state of the storage device is written to 0, thereby completing the writing of information.

In combination with the embodiments described above, an operation method for a storage array is further provided in the present disclosure, which includes:
when performing a read operation on the storage array, controlling the voltage of the word line to turn on the N gating transistors of the storage cell to be read and then applying a read signal to the corresponding bit line and reading the current of the corresponding source line to read out the resistance state of the storage device; and
when performing a write operation on the storage array, controlling the voltage of the word line to turn on the N gating transistors of the storage cell to be written and then applying a write signal to the bit line or the source line to change the resistance value of the storage device, so as to write a desired state into the storage device. The above explains a method for operating a single storage cell in the array at a time, where only one row or one column is gated each time. Those skilled in the art should understand that this reading or writing method can be readily extended to a storage array having multiple rows and multiple columns, so as to read or write storage cells in the multiple rows or the multiple columns in parallel, thereby increasing the data throughput of the storage array.

According to the embodiments of the present disclosure, by connecting a gating transistor to multiple storage devices and using a structure in which gating transistors are connected to each other in sequence, the area overhead of connecting the gating transistors to external source lines SL is eliminated. In terms of storage density, the storage array provided in the present disclosure is larger than the existing 1T1R storage array, which is beneficial to reducing the area of the storage cells, thereby improving integration density of the storage array and reducing the cost of manufacturing memories.

It should be noted that in a structure of the storage cell provided in the present disclosure, the number of storage devices connected to each of the gating transistors may be different. Similarly, an array structure provided in the present disclosure may be formed by arranging storage cells of different sizes provided in the present disclosure. The above changes do not affect the corresponding characteristics and beneficial effects of the present disclosure and do not change the essence of the present disclosure.

Finally, it should be noted that the objective of disclosing the embodiments is for further understanding to the present disclosure. However, those skilled in the art can understand that various substitutions and modifications are feasible without departing from the essence and scope of the present disclosure and the appended claims. Therefore, the present disclosure should not be limited to the content disclosed in the embodiments, and the protection scope of the present disclosure is subject to the definition of the claims.

What is claimed is:

1. A storage array, comprising K storage cells arranged in parallel, wherein each of the storage cells comprises N gating transistors, N×M two-end storage devices, a source line, a word line, and N×M bit lines, a drain-source series structure is formed by connecting a drain of a previous gating transistor to a source of a subsequent gating transistor among the N transistors, gates of the drain-source series structure are all connected to the word line, a source of the first gating transistor in the drain-source series structure is connected to the source line, every M two-end storage devices are grouped, with a total of N groups corresponding to the N gating transistors, ends of the storage devices in each of the groups are interconnected and connected to the drain of the corresponding gating transistor, the other ends of the storage devices are connected to M bit lines respectively, the K storage cells of the storage array share N×M common bit lines, and N×M bit lines of each of the storage cells are connected to the N×M common bit lines, respectively.

2. The storage array according to claim 1, wherein the two-end storage device has at least two variable states for storing data, and the two-end storage device comprises a resistive random access memory, a spin transfer torque magnetoresistive random access memory, or a phase-change random storage.

3. The storage array according to claim 1, wherein the gating transistor comprises a MOSFET.

4. The storage array according to claim 1, wherein K is not smaller than two.

5. An operation method for a storage array according to claim 1, comprising:
controlling a voltage of a word line to turn on N gating transistors of a storage cell to be read when performing a read operation on the storage array, and then applying a read signal to a corresponding bit line and reading a current of a corresponding source line to read a resistance state of a storage device; or
controlling a voltage of the word line to turn on N gating transistors of a storage cell to be written when performing a write operation on the storage array, and then applying a write signal to a bit line or a source line to change a resistance state of a storage device.
